(19) United States
(12) Patent Application Publication
(10) Pub. No.: US 2024/0425718 A1
(43) Pub. Date: Dec. 26, 2024

(54) UNDERFILL COMPOSITION

(71) Applicant: Shin-Etsu Chemical Co., Ltd., Tokyo (JP)

(72) Inventors: Yuri ITO, Annaka-shi (JP); Naoyuki KUSHIHARA, Annaka-shi (JP); Kazuaki SUMITA, Annaka-shi (JP)

(73) Assignee: Shin-Etsu Chemical Co., Ltd., Tokyo (JP)

(21) Appl. No.: 18/734,028

(22) Filed: Jun. 5, 2024

(30) Foreign Application Priority Data
Jun. 14, 2023 (JP) 2023-097507
Oct. 27, 2023 (JP) 2023-184618

(51) Int. Cl. C09D 163/00; C09D 7/40; C09D 7/61; C09D 7/63; H01L 23/29

(52) U.S. Cl. CPC C09D 163/00; C09D 7/61; C09D 7/63; C09D 7/70; H01L 23/295

(57) ABSTRACT

Provided is an underfill composition having a low relative permittivity and a low dielectric tangent. The underfill composition contains the components of: (A) a citraconimide compound; (B) an epoxy resin; (C) an epoxy resin curing agent; (D) a curing accelerator, and (E) an inorganic filler, wherein the citraconimide compound (A) is a biscitraconimide compound represented by the following formula (1):

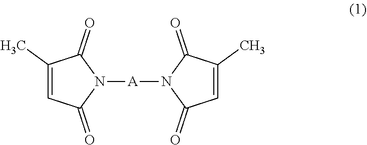

wherein A in the formula (1) represents a divalent organic group.

### BACKGROUND OF THE INVENTION

### Field of the Invention

The present invention relates to an underfill composition using a citraconimide compound.

### Background Art

The dominant process for mounting semiconductor chips has shifted from pin insertion to surface mounting, driven by the trend of electronic devices becoming smaller, lighter, and more sophisticated. Particularly, the flip chip method is a semiconductor chip mounting technique where a semiconductor chip is mounted on the wiring pattern surface of an organic substrate using multiple solder bumps, and an underfill material is filled to bridge the gap between the organic substrate and the semiconductor chip, as well as the gaps between the individual solder bumps (JP-A-2022-63247).

In recent years, the speed of signals used in electronic devices-such as mobile communication devices (e.g., mobile phones), their base station equipment, network infrastructure equipment (such as servers and routers), and large-scale computers—and the capacities of these devices have consistently increased year after year. In view of such a trend, printed-wiring boards integrated into these electronic devices must exhibit compatibility with higher frequencies, particularly those in the 20 GHz range. Consequently, there is a demand for underfill materials possessing low-dielectric properties such as low relative permittivity and low dielectric tangent, which enable minimization of transmission loss during signal propagation. In addition to the aforementioned electronic devices, practical applications of novel systems employing high-frequency wireless signals are progressively underway or even put to actual use in fields such as Intelligent Transportation Systems (ITS) (relating to automobile and transportation systems) and indoor short-range communication. Consequently, there is also demand for underfill materials possessing low-dielectric properties in the design of printed-wiring boards intended for installation in these devices. Furthermore, an underfill material with a low Coefficient of Linear Thermal Expansion (CTE) is highly regarded for mitigating material warpage and improving substrate manufacturing yield.

Epoxy resins, commonly employed as underfill materials, tend to exhibit relatively high relative permittivity and dielectric tangent (JP-A-2022-133311). Meanwhile, heat-curable resins, including a modified polyphenylene ether resin and a maleimide resin, as well as thermoplastic resins such as a fluorine resin, a styrene resin, and liquid crystal polymers are known as materials exhibiting low relative permittivity and dielectric tangent (JP-A-2022-77400, JP-A-2019-99710, JP-A-2018-177931, JP-A-2022-1628 and JP-A-2022-35328). However, although they are suitable for use in a printed-wiring board or the like, these materials have high melt viscosities and the resultant cured products thereof are hard and brittle, which therefore pose a challenge for use as semiconductor encapsulation materials for underfills. JP-A-2023-018240 and JP-A-2022-147022 disclose that citraconic imide resin compositions can yield cured products with excellent dielectric and heat resistance properties. However, up until now, no exploration has ever been undertaken regarding its potential application to underfill material.

### SUMMARY OF THE INVENTION

Thus, it is an object of the present invention to provide an underfill composition that is superior in infiltration property, and is capable of being turned into a cured product having a low relative permittivity and a low dielectric tangent.

It is also an object of the invention to provide an underfill composition that is superior in infiltration property, wherein specific components are further added to turn the composition into a cured product having superior dielectric properties (a low relative permittivity and a low dielectric tangent) and adhesiveness.

The inventors of the present invention diligently conducted a series of studies to solve the above problem, and have found that the underfill composition containing a citraconic imide compound, as defined below, can achieve the above-mentioned object, and thus have completed the invention.

That is, the present invention provides the following underfill composition.

[1] An underfill composition comprising the components of:
(A) a citraconimide compound;
(B) an epoxy resin;
(C) an epoxy resin curing agent;
(D) a curing accelerator; and
(E) an inorganic filler.

[2] The underfill composition according to [1], wherein, based on the mass of the whole composition, the citraconimide compound (A) is contained therein in an amount of 10 to 75% by mass, the epoxy resin (B) is contained therein in an amount of 0.1 to 75% by mass, the epoxy resin curing agent (C) is contained therein in an amount such that a molar equivalent ratio of functional groups in the component (C) that are reactive with epoxy groups to 1 molar equivalent of epoxy groups in the epoxy resin (B) is 0.1 to 8.0, and the curing accelerator (D) is contained therein in an amount of 0.0001 to 15% by mass.

[3] The underfill composition according to [1] or [2], wherein the citraconimide compound (A) is a biscitraconimide compound represented by the following formula (1):

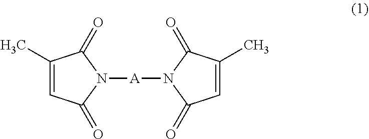

wherein A in the formula (1) represents a divalent organic group.

[4] The underfill composition according to [3], wherein A in the formula (1) is selected from dimer acid frame-derived hydrocarbon groups, and the groups expressed by the following structures:

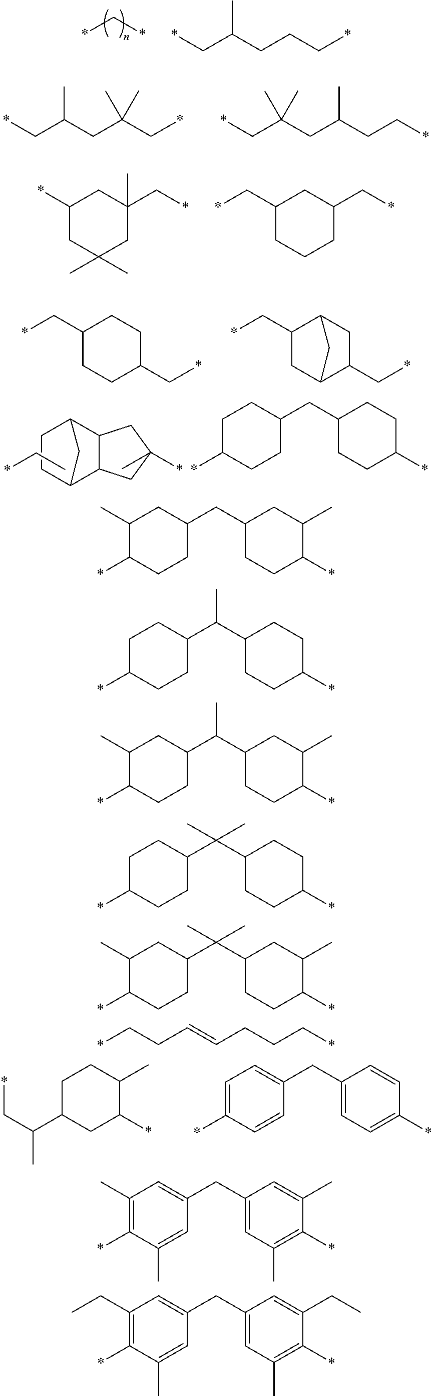

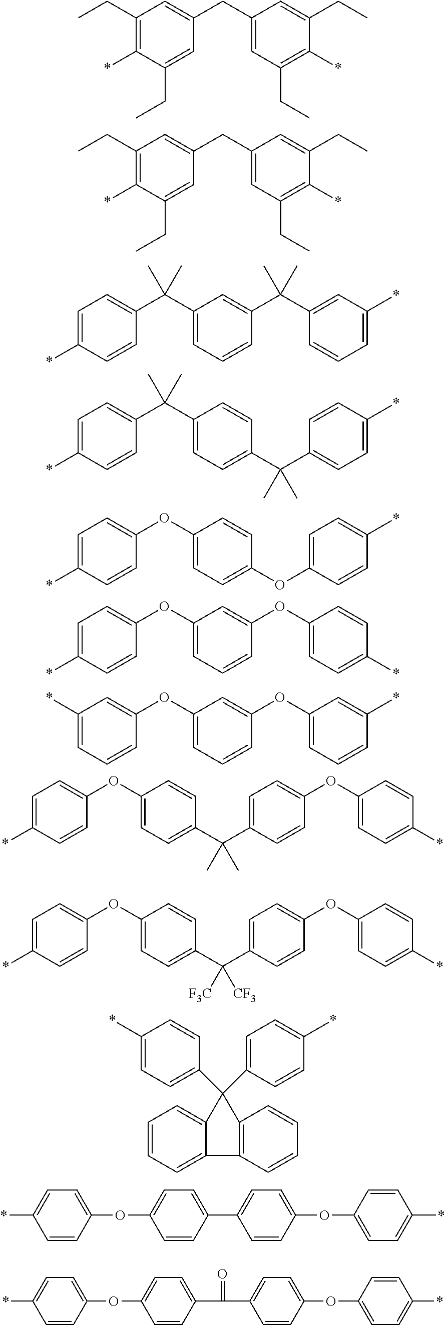

wherein each * represents a bond to a nitrogen atom in the citraconimide group; and n is 1 to 20.

[5] The underfill composition according to [3], wherein A in the formula (1) is a group selected from the aliphatic hydrocarbon groups expressed by the following structures:

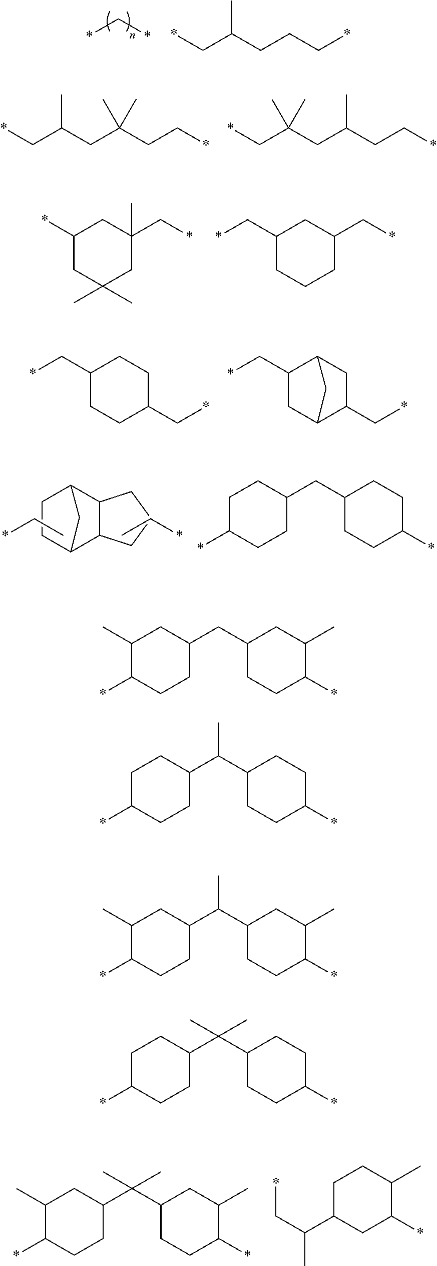

wherein each * represents a bond to a nitrogen atom in the citraconimide group; and n is 1 to 20.

[6] The underfill composition according to any one of [1] to [5], wherein the citraconimide compound (A) has a number average molecular weight of 200 to 10,000.

[7] The underfill composition according to any one of [1] to [6], wherein the epoxy resin (B) has at least two epoxy groups per each molecule.

[8] The underfill composition according to any one of [1] to [7], wherein the epoxy resin curing agent (C) is at least one selected from an amine compound, a phenolic compound, an acid anhydride compound and an active ester compound.

[9] The underfill composition according to any one of [1] to [8], wherein the curing accelerator (D) contains at least one selected from an imidazole-based curing accelerator, an organic phosphorus-based curing accelerator and a tertiary amine-based curing accelerator.

The underfill composition according to any one of [1] to [9], wherein the inorganic filler (E) is a spherical silica having an average particle diameter of 0.01 to 5 μm, wherein the spherical silica is manufactured by a sol-gel process.

The underfill composition according to any one of [1] to [10], wherein the inorganic filler (E) is contained therein in an amount of 20 to 80% by mass per 100% by mass of the whole components in the composition.

The underfill composition according to any one of [1] to [11], further comprising at least one silane coupling agent represented by the following formula (4):

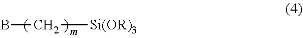

wherein, in the formula (4), each R independently represents a methyl group or an ethyl group, m is a number of 8 to 12, and B is a monovalent organic group having, at its terminal end, one functional group selected from an epoxy group, a glycidoxy group, an acryloxy group, a methacryloxy group and an amino group.

The underfill composition of the present invention is superior in infiltration property, and the cured product thereof has excellent dielectric properties (a low relative permittivity and a low dielectric tangent) and adhesiveness. The composition of the present invention is therefore suitable for use as an underfill material.

### DETAILED DESCRIPTION OF THE INVENTION

The present invention is described in detail hereunder.

### (A) Citraconimide Compound

A component (A) used in the present invention is a citraconimide compound. The citraconimide group is a group obtained by substituting one hydrogen atom in a maleimide group with a methyl group. Due to the effect of this methyl group, and as compared to a maleimide compound having the same frame, such cured product not only exhibits a lower permittivity and a lower dielectric tangent, but the compound itself also has a lower melting point such that compatibility thereof to other components will be improved as well.

Although the properties under room temperature and a number average molecular weight of the citraconimide compound as the component (A) will not particularly be limited; it is preferred that this number average molecular weight be 200 to 10,000, more preferably 200 to 5,000, even more preferably 200 to 2,000.

In this specification, the term “number average molecular weight” as used herein refers to a number average molecular weight in terms of polystyrene that is measured by gel permeation chromatography (GPC) under the following measurement conditions.

### [GPC Measurement Conditions]

Developing solvent: Tetrahydrofuran (THF)
Flow rate: 0.35 mL/min
Detector: Differential refractive index detector (RI)
Column: TSK Guardcolumn SuperH-L
   TSKgel SuperHZ 4000 (4.6 mm I.D.×15 cm×1)
   TSKgel SuperHZ 3000 (4.6 mm I.D.×15 cm×1)
   TSKgel SuperHZ 2000 (4.6 mm I.D.×15 cm×2)
   (All manufactured by Tosoh Corporation)
Column temperature: 40° C.
Sample injection volume: 5 μL (THF solution with a concentration of 0.2% by mass)

In terms of availability of an amine compound as a raw material, solubility of the citraconimide compound in a solvent, and ease of synthesis of the citraconimide compound, it is preferred that the citraconimide compound as the component (A) be a biscitraconimide compound having two citraconimide groups per each molecule, particularly preferably a biscitraconimide compound represented by the following formula (1):

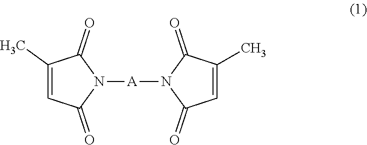

wherein A has a divalent organic group.

Further, in order to achieve a low elasticity and excellent dielectric properties (having low relative permittivity and low dielectric tangent) after being cured, it is more preferred that the divalent organic group represented by “A” in the citraconimide compound be the one selected from the groups of the following structures and dimer acid frame-derived hydrocarbon groups:

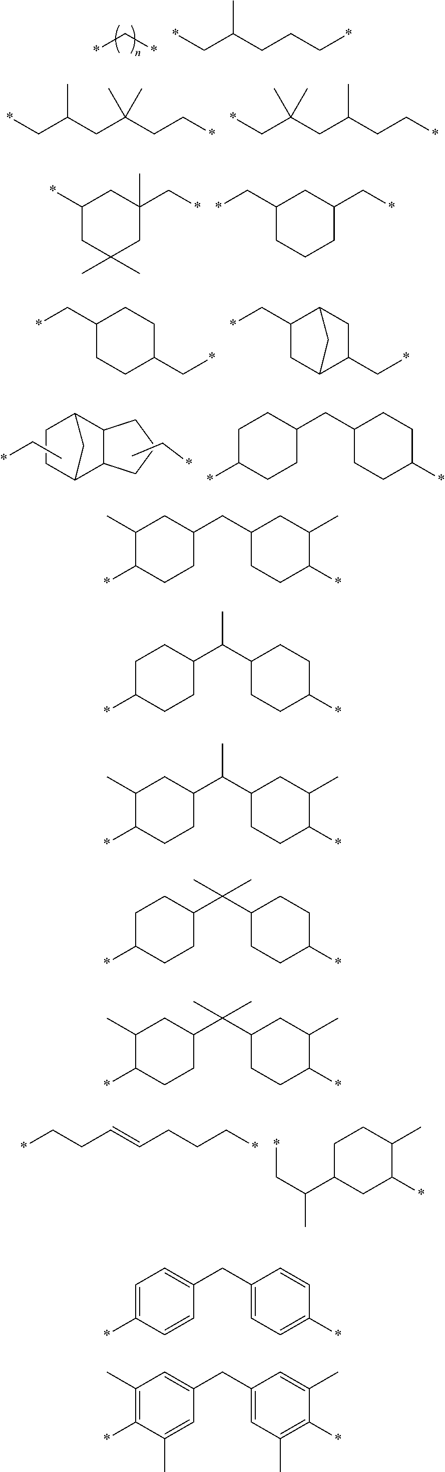

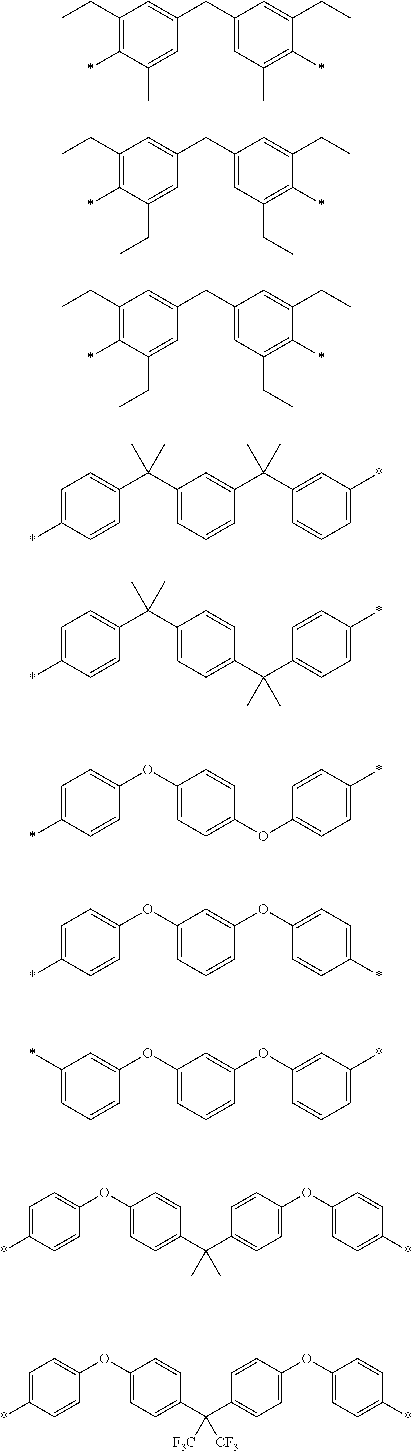

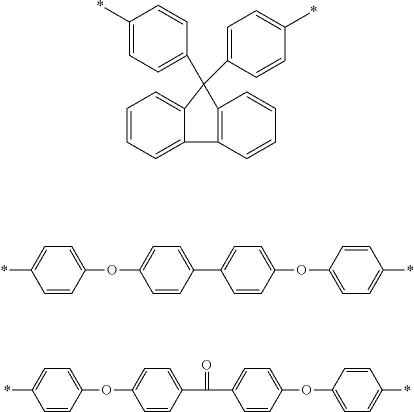 [SMILES: *c1ccc(C2(c3ccc(*)cc3)c3ccccc3-c3ccccc32)cc1 ; *c1ccc(Oc2ccc(-c3ccc(Oc4ccc(*)cc4)cc3)cc2)cc1 ; *c1ccc(Oc2ccc(C(=O)c3ccc(Oc4ccc(*)cc4)cc3)cc2)cc1]

wherein each * represents a bond to a nitrogen atom in the citraconimide group; n is 1 to 20.

Among the above-listed divalent organic groups, it is even more preferred that A be a group selected from the aliphatic hydrocarbon groups as defined by the following structures:

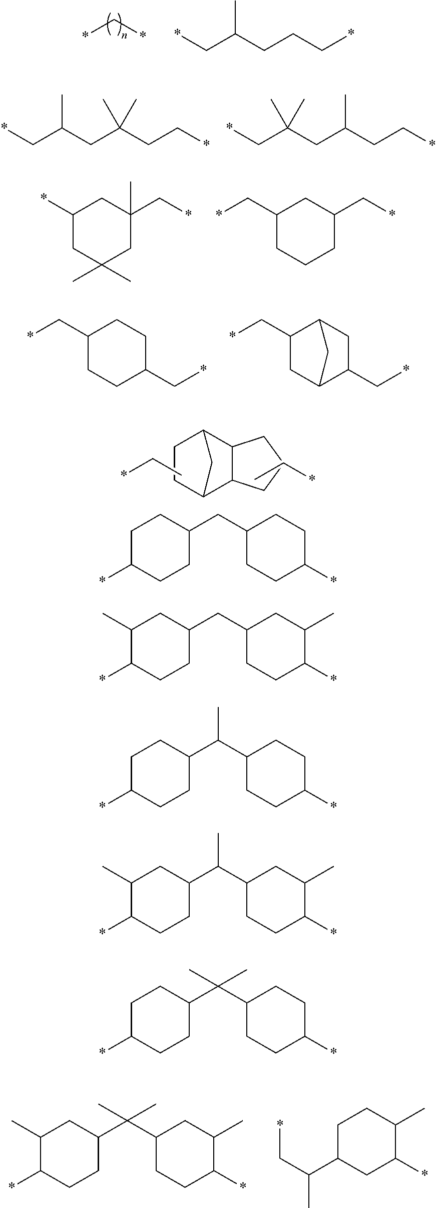

wherein each * represents a bond to a nitrogen atom in the citraconimide group; and n is 1 to 20.

Further, in terms of lowering the viscosity of the underfill composition, it is particularly preferred that the divalent organic group represented by A be a hydrocarbon group containing a linear or alicyclic structure but no aromatic ring, such as a group induced from a diamine such as 2-methyl-pentamethylenediamine, 2,2,4-trimethylhexamethylenediamine or 1,4-cyclohexanedimethanamine (i.e. a group obtained by removing two amino groups from any of these diamines).

The term “dimer acid” refers to a liquid dibasic acid whose main component is a dicarboxylic acid having 36 carbon atoms, and is produced by dimerizing unsaturated fatty acids having 18 carbon atoms and whose raw material is a natural ingredient such as a vegetable fat or oil. A dimer acid frame is not limited to a single type of frame but may have multiple types of structures, where there may exist several types of isomers thereof. Typical dimer acids are grouped into the categories of (a) linear type, (b) monocyclic type, (c) aromatic ring type, and (d) polycyclic type.

The term “dimer acid frame” as used herein refers to a group derived from a dimer diamine having a structure established by substituting the carboxy group(s) in such dimer acid with a primary aminomethyl group.

That is, as the dimer acid frame-derived hydrocarbon group of the citraconimide compound as the component (A), it is preferred that the hydrocarbon group be a branched divalent hydrocarbon group obtained by substituting the two carboxy groups in any of the dimer acids represented by the following formulae (a) to (d) with methylene groups.

Further, when the citraconimide compound, as component (A), contains a dimer acid frame-derived hydrocarbon group, it is more preferable for such dimer acid frame-derived hydrocarbon group to have fewer carbon-carbon double bonds through hydrogenation for enhancing the heat resistance and reliability of the cured product.

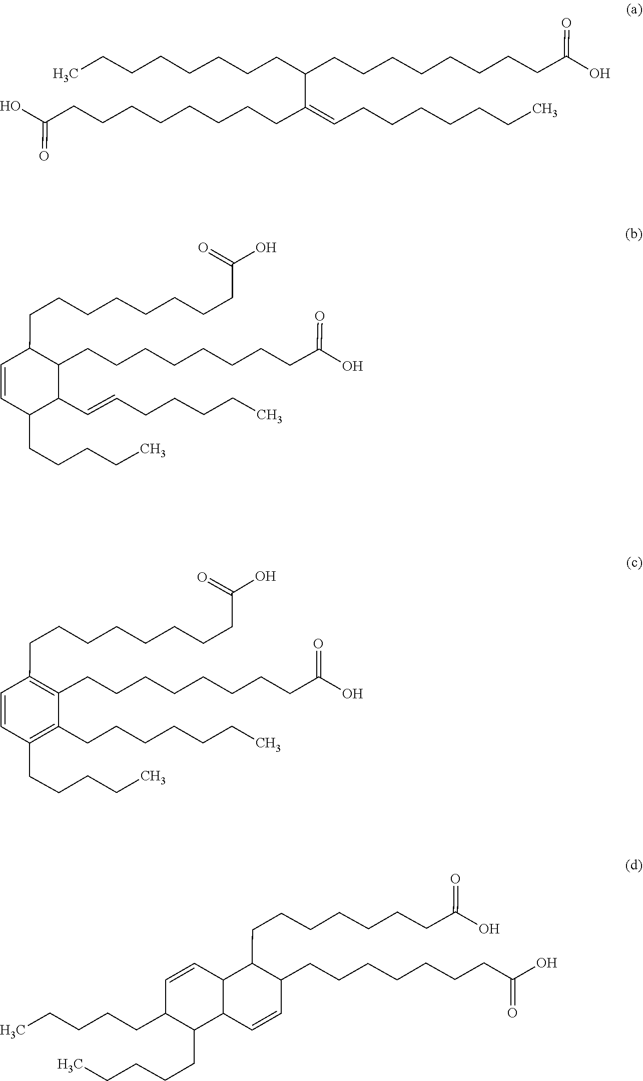 [SMILES: CCCCCCC/C=C(/CCCCCCCCC(=O)O)C(CCCCCCCC)CCCCCCCCC(=O)O ; CCCCC/C=C/C1C(CCCCC)C=CC(CCCCCCCCC(=O)O)C1CCCCCCCCC(=O)O ; CCCCCCCc1c(CCCCC)ccc(CCCCCCCCC(=O)O)c1CCCCCCCCC(=O)O ; CCCCCC1C=CC2C(C=CC(CCCCCCCC(=O)O)C2CCCCCCCC(=O)O)C1CCCCC]

One kind of the citraconimide compound as the component (A) may be used alone, or two or more kinds thereof may be used in combination.

In the underfill composition of the present invention, it is preferred that the component (A) be contained in an amount of 10 to 75% by mass, more preferably 20 to 65% by mass, even more preferably 30 to 50% by mass, based on the mass of the whole composition.

### (B) Epoxy Resin

An epoxy resin (B) is added to promote a reaction of the citraconimide compound (A).

It is preferred that this epoxy resin have at least two epoxy groups per each molecule, and there may be used a conventionally known epoxy resin.

For example, there may be listed bisphenol-type epoxy resins such as a bisphenol A-type epoxy resin, a bisphenol F-type epoxy resin and a bisphenol S-type epoxy resin; novolac-type epoxy resins such as a phenol novolac-type epoxy resin, a cresol novolac-type epoxy resin, a bisphenol A novolac-type epoxy resin and a bisphenol F novolac-type epoxy resin; alicyclic epoxy resins such as a dicyclopentadiene-type epoxy resin and 3,4-epoxycyclohexenylmethyl-3′,4′-epoxycyclohexene carboxylate; polyfunctional phenol-type epoxy resins such as a resorcinol-type epoxy resin and a resorcinol novolac-type epoxy resin; a stilbene-type epoxy resin; a triazine frame-containing epoxy resin; a fluorene frame-containing epoxy resin; a triphenolalkane-type epoxy resin; a biphenyl-type epoxy resin; a xylylene-type epoxy resin; a biphenyl aralkyl-type epoxy resin; a naphthalene-type epoxy resin; diglycidylether compounds of polycyclic aromatics such as anthracene; and a phosphorus-containing epoxy resin obtained by introducing a phosphorus compound into any of these resins and compounds. Particularly, a bisphenol A-type epoxy resin, a dicyclopentadiene-type epoxy resin, a biphenyl aralkyl-type epoxy resin and a naphthalene-type epoxy resin are preferably used.

Any one kind of the above-listed resins and compounds may be used alone, or two or more kinds of them may be used in combination.

The component (B) is in an amount of 0.1 to 75% by mass, preferably 0.5 to 50% by mass, more preferably 1 to 25% by mass, based on the mass of the whole composition. When the amount of the epoxy resin (B) contained is within these ranges, there can be obtained a cured product having low dielectric properties (having low permittivity and low dielectric tangent).

### (C) Epoxy Resin Curing Agent

An epoxy resin curing agent (C) is added for making it react with the epoxy groups contained in the epoxy resin (B). The epoxy resin curing agent may simply be that containing a functional group(s) reactive with epoxy groups; particularly, preferred is at least one kind selected from an amine compound, a phenolic compound, an acid anhydride compound and an active ester compound. Of these, a phenolic compound is more preferred in view of the dielectric property of the composition.

As an amine compound, a generally known amine compound may be used. An aromatic amine compound is preferred in terms of handling property and moisture resistance reliability. Preferable examples of such aromatic amine compound include an aromatic diaminodiphenylmethane compound such as 3,3′-diethyl-4,4′-diaminodiphenylmethane, 3,3′,5,5′-tetramethyl-4,4′-diaminodiphenylmethane or 3,3′,5,5′-tetraethyl-4,4′-diaminodiphenylmethane; 2,4-diaminotoluene; 1,4-diaminobenzene; and 1,3-diaminobenzene. More preferred are aromatic diaminodiphenylmethane compounds such as 3,3′-diethyl-4,4′-diaminodiphenylmethane, 3,3′,5,5′-tetramethyl-4,4′-diaminodiphenylmethane and 3,3′,5,5′-tetraethyl-4,4′-diaminodiphenylmethane. Any one kind of these compounds may be used alone, or two or more kinds of them may be used in combination.

The amine compound may be either a liquid or a solid at normal temperature (20 to 30° C.). An amine compound being a liquid at normal temperature may be added as it is without problem. However, in the case of an amine compound being solid at normal temperature, if such compound is added as it is, the viscosity of the resin composition will rise, and workability will thus be significantly impaired; it is therefore preferred that the amine compound be previously melted and mixed with the abovementioned epoxy resin, more specifically, it is preferred that such amine compound be melted and mixed with the epoxy resin at a later-described particular compounding ratio and at a temperature of 70 to 150° C. for one to two hours. If the mixing temperature is lower than 70° C., the amine compound may not be compatible enough; if the mixing temperature is greater than 150° C., a rise in viscosity may be observed due to the reaction with the epoxy resin. Further, if the mixing time is shorter than one hour, a rise in viscosity may be incurred due to insufficient compatibility of the amine compound; if the mixing time is longer than two hours, a rise in viscosity may be observed due to the reaction with the epoxy resin.

As a phenolic compound, a generally known phenolic compound may be used. For example, there may be listed a phenol novolac resin, a naphthalene ring-containing phenolic resin, an aralkyl-type phenolic resin, a triphenolalkane-type phenolic resin, a biphenyl frame-containing aralkyl-type phenolic resin, a biphenyl-type phenolic resin, an alicyclic phenolic resin, a heterocyclic phenolic resin, a naphthalene ring-containing phenolic resin, a resorcinol-type phenolic resin, an allyl group-containing phenolic resin such as a novolac-type allylphenolic resin, and a bisphenol-type phenolic resin such as a bisphenol A-type resin or a bisphenol F-type resin. Any one kind of these compounds may be used alone, or two or more kinds of them may be used in combination.

As an acid anhydride compound, a generally known acid anhydride compound may be used. For example, there may be listed 4-methylcyclohexane-1,2-dicarboxylic acid anhydride, 3,4-dimethyl-6-(2-methyl-1-propenyl)-1,2,3,6-tetrahydrophthalic anhydride, 1-isopropyl-4-methyl-bicyclo[2.2.2]oct-5-en-2,3-dicarboxylic acid anhydride, methyltetrahydrophthalic anhydride, methylhexahydrophthalic anhydride, hexahydrophthalic anhydride, methylhymic acid anhydride, pyromellitic acid dianhydride, maleated allo-ocimene, benzophenone tetracarboxylic acid dianhydride, 3,3′,4,4′-biphenyltetrabisbenzophenone tetracarboxylic acid dianhydride, (3,4-dicarboxyphenyl) ether dianhydride, bis(3,4-dicarboxyphenyl) methane dianhydride, and 2,2-bis(3,4-dicarboxyphenyl) propane dianhydride. Any one kind of these compounds may be used alone, or two or more kinds of them may be used in combination.

As an active ester compound, a generally known active ester compound may be used. For example, there may be listed an active ester compound having a dicyclopentadiene-type phenolic resin structure, an active ester compound having a phenol novolac structure, an active ester compound having a naphthalene ring structure, an active ester compound having an aralkyl-type phenolic resin structure, an active ester compound having a triphenolalkane-type phenolic resin structure, an active ester compound having a biphenyl frame-containing aralkyl-type phenolic resin structure, an active ester compound having a biphenyl-type phenolic resin structure, an active ester compound having an alicyclic phenolic resin structure, an active ester compound having a heterocyclic phenolic resin structure, an active ester compound having a naphthalene ring-containing phenolic resin structure, an active ester compound having a resorcinol-type phenolic resin structure, an active ester compound having an allyl group-containing phenolic resin structure, an active ester compound having a bisphenol A-type resin structure, and an active ester compound having a bisphenol-type phenolic resin structure such as a bisphenol F-type resin structure. Any one kind of these compounds may be used alone, or two or more kinds of them may be used in combination.

The epoxy resin curing agent is added preferably in an amount at which a molar equivalent ratio of the functional groups in the epoxy resin curing agent to 1 molar equivalent of the epoxy groups in the component (B) will be 0.1 to 8.0, more preferably 0.5 to 6.0, particularly preferably 1.0 to 4.0. When this molar equivalent ratio is lower than 0.1, unreacted epoxy groups will remain so that an adhesiveness may deteriorate; when this molar equivalent ratio is greater than 8.0, a moisture absorption rate of the cured product will increase so that cracks may occur at the time of performing reflow or temperature cycling. Here, in the present invention, the term “equivalent” refers to a molecular weight per one functional group.

### (D) Curing Accelerator

A curing accelerator as a component (D) may simply be the one capable of promoting the curability of the citraconimide compound (A); there may be used a generally known curing accelerator such as an imidazole-based curing accelerator, an organic phosphorus-based curing accelerator, and a tertiary amine-based curing accelerator. Of these, it is preferable to use an imidazole-based curing accelerator to suppress the viscosity of the composition.

As the curing accelerator as the component (D), there may be listed, for example, a phosphine such as triphenylphosphine, tributylphosphine, tri (p-methylphenyl)phosphine or tri (nonylphenyl)phosphine; a phosphine-borane complex such as triphenylphosphine-triphenylborane; a phosphonium borate salt such as tetraphenylphosphonium tetraphenylborate, tetraphenylphosphonium tetra-p-tolylborate, p-tolyltriphenylphosphonium tetra-p-tolylborate or tri-tert-butylphosphonium tetraphenylborate; an organic phosphorus-based compound such as bis(tetrabutylphosphonium)dihydrogen pyromellitate; a tertiary amine compound such as triethylamine, benzyldimethylamine, α-methylbenzyldimethylamine or 1,8-diazabicyclo [5.4.0]undecene-7; a salt of a tertiary amine compound such as 1,8-diazabicyclo[5.4.0]undecene-7; and an imidazole compound such as 2-methylimidazole, 2-phenylimidazole, 2-ethyl-4-methylimidazole or 2-phenyl-4-methylimidazole. Particularly, preferred are a salt of a tertiary amine compound and an organic phosphorus-based compound; more preferred are a salt of 1,8-diazabicyclo[5.4.0]undecene-7 and tetraphenylphosphonium tetraphenylborate.

One kind of the component (D) may be used alone, or two or more kinds thereof may be used in combination.

The component (D) may be contained therein in an amount of 0.0001 to 15% by mass, more preferably 0.001 to 10% by mass, even more preferably 0.01 to 5% by mass based on the mass of the whole composition.

### (E) Inorganic Filler

An inorganic filler (E) is added to enhance the resin strength of the underfill composition and realize a lower thermal expansivity.

Examples of the inorganic filler include silicas (e.g., molten silica, crystalline silica, cristobalite), alumina, silicon nitride, aluminum nitride, boron nitride, titanium oxide, glass fibers and magnesium oxide.

It is preferred that the particle diameter of these inorganic fillers be appropriately adjusted based on the gap size of semiconductor devices, which is essentially the width of the gap between the substrate and the semiconductor chip. The typical gap size is typically 10 to 200 μm. In this case, in view of the viscosity of the underfill composition and the linear coefficient of expansion of the cured product, it is preferred that the inorganic filler be a spherical silica having an average particle diameter (referred to as d50 or median diameter) of 0.01 to 5 μm, more preferably of 0.05 to 2 μm, where the average particle diameter is a volume average median diameter as measured by a laser diffraction particle size distribution measurement device.

To control the average particle diameter and particle diameter distribution of the inorganic filler (E), the sol-gel method or the vaporized metal combustion method is most suitable. A spherical silica produced using these methods has an advantage of being truly spherical compared to fused silica, and its particle diameter distribution can be easily designed. Both the sol-gel and the vaporized metal combustion methods may be conventional techniques that are well-known. Specifically, from the perspective of thin film penetration, it is even more preferable to use a silica manufactured via the sol-gel method.

It is preferred that the inorganic filler (E) be composed of a spherical silica manufactured by a sol-gel process in an amount of at least 80% by mass, particularly 95 to 100% by mass based on the mass of the whole inorganic filler (E). An underfill composition having a content of 80% by mass or more exhibits favorable flowability.

It is preferred that the amount of the inorganic filler (E) contained in the composition be 20 to 80% by mass, more preferably 40 to 60% by mass per 100% by mass of the whole components in the composition. The content of less than 20% by mass may result in a cured product having a large expansion coefficient. The content exceeding 80% by mass may increase the viscosity of the underfill composition, which is detrimental to the infiltration property into the gap.

It is preferred that the employed inorganic filler be the one which is previously surface-treated with a coupling agent such as a silane coupling agent or a titanate coupling agent to enhance the bonding strength between the organic filler and the components (A) and (B). Examples of such coupling agent include silane coupling agents such as an epoxysilane, an aminosilane and a mercaptosilane, of which the epoxysilane may for example be 3-glycidoxypropyltrimethoxysilane, 3-glycidoxypropylmethyldiethoxysilane, or 2-(3,4-epoxycyclohexyl)ethyltrimethoxysilane; the aminosilane may for example be N-2 (aminoethyl)-3-aminopropyltrimethoxysilane, a reactant of imidazole and 3-glycidoxypropyltrimethoxysilane, 3-aminopropyltriethoxysilane, or N-phenyl-3-aminopropyltrimethoxysilane; and the mercaptosilane may for example be 3-mercaptopropyltrimethoxysilane or 3-episulfidoxypropyltrimethoxysilane. Here, there are no particular restrictions on the amount of the coupling agent used for surface treatment and a surface treatment method.

### (F) Silane Coupling Agent

A silane coupling agent (F) may be added, as necessary, for enhancing an adhesion force of the underfill composition to a base material.

It is preferred that the silane coupling agent for use in the present invention be a compound represented by the following formula (4):

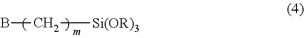

wherein, in the formula (4), each R independently represents an alkyl group having one or two carbon atoms, m is a number of 8 to 12, and B is a monovalent organic group having, at its terminal end, one functional group selected from an epoxy group, a glycidoxy group, an acryloxy group, a methacryloxy group and an amino group.

Examples of the silane coupling agent as being the component (F) include silane coupling agents of, for example, (9,10-epoxydecyl)trimethoxysilane, (9,10-epoxydecyl)triethoxysilane, (11,12-epoxydodecyl)trimethoxysilane, 8-glycidoxyoctyltrimethoxysilane, 8-glycidoxyoctyltriethoxysilane, 11-glycidoxyundecyltrimethoxysilane, 8-acryloxyoctyltrimethoxysilane, 8-acryloxyoctyltriethoxysilane, 8-methacryloxyoctyltrimethoxysilane, 8-mathacryloxyoctyltriethoxysilane, 11-methacryloxyundecyltrimethoxysilane, 8-aminooctyltrimethoxysilane, 11-aminoundecyltrimethoxysilane, 8-aminooctyltriethoxysilane, N-2-(aminoethyl)-8-aminooctyltrimethoxysilane and N-2-(aminoethyl)-8-aminooctyltriethoxysilane.

The silane coupling agent as expressed by the formula (4) may be used alone, or the agent may be used as a combination of two or more types of silane coupling agents including not only the agent expressed by the formula (4) but also one or more compounds that are not expressed by the formula (4).

Although there are no particular restrictions on a silane coupling agent, examples of the one or more compounds that are not expressed by the formula (4) include, for example, n-propyltrimethoxysilane, n-propyltriethoxysilane, n-octyltrimethoxysilane, n-octyltriethoxysilane, phenyltrimethoxysilane, phenyltriethoxysilane, methyltrimethoxysilane, methyltriethoxysilane, 2-[methoxy (polyethyleneoxy) propyl]-trimethoxysilane, methoxytri(ethyleneoxy) propyltrimethoxysilane, 3-glycidoxypropyltrimethoxysilane, 3-aminopropyltrimethoxysilane, 3-mercaptopropyltrimethoxysilane, 3-(methacryloyloxy) propyltrimethoxysilane, 3-isocyanatopropyltriethoxysilane and 3-isocyanatopropyltrimethoxysilane.

The component (F) expressed by the formula (4) may be contained therein in an amount of 0.1 to 5% by mass, preferably 0.5 to 3% by mass based on the mass of the whole composition. Also, it is preferred that the silane coupling agent not expressed by the formula (4) be contained in an amount of 0 to 5% by mass, more preferably 0.1 to 3% by mass based on the mass of the whole composition.

### Other Additives

In addition to the components (A) to (E), other additives may also be added to the underfill composition of the present invention, if necessary, provided that the purposes and effects of the present invention will not be impaired. Examples of such additives include a flame retardant, an ion trapping agent, an antioxidant, an adhesiveness imparting agent, a low-stress agent and a colorant.

A flame retardant may be added to impart a flame retardancy. There are no particular restrictions on such flame retardant, and any known flame retardant can be used; examples of which include a phosphazene compound, a silicone compound, a zinc molybdate-supported talc, a zinc molybdate-supported zinc oxide, aluminum hydroxide, magnesium hydroxide and molybdenum oxide.

An ion-trapping agent may be added to prevent heat deterioration and moisture absorption deterioration by trapping the ion impurities contained in the composition. There are no particular restrictions on such ion-trapping agent, and any known ion trapping agent can be used; examples of which include hydrotalcites, a bismuth hydroxide compound and a rare-earth oxide.

Examples of the antioxidant include, but are not particularly limited to, a phenol-based antioxidant such as n-octadecyl-3-(3,5-di-t-butyl-4-hydroxyphenyl) propionate, n-octadecyl-3-(3,5-di-t-butyl-4-hydroxyphenyl)acetate, neododecyl-3-(3,5-di-t-butyl-4-hydroxyphenyl) propionate, dodecyl-β-(3,5-di-t-butyl-4-hydroxyphenyl) propionate, ethyl-α-(4-hydroxy-3,5-di-t-butylphenyl) isobutyrate, octadecyl-α-(4-hydroxy-3,5-di-t-butylphenyl) isobutyrate, octadecyl-α-(4-hydroxy-3,5-di-t-butyl-4-hydroxyphenyl) propionate, 2-(n-octylthio)ethyl-3,5-di-t-butyl-4-hydroxyphenyl acetate, 2-(n-octadecylthio)ethyl-3,5-di-t-butyl-4-hydroxyphenyl acetate, 2-(n-octadecylthio)ethyl-3-(3,5-di-t-butyl-4-hydroxyphenyl) propionate, 2-(2-stearoyloxyethylthio)ethyl-7-(3-methyl-5-t-butyl-4-hydroxyphenyl) heptanoate, 2-hydroxyethyl-7-(3-methyl-5-t-butyl-4-hydroxyphenyl) propionate or pentaerythritol tetrakis[3-(3,5-di-t-butyl-4-hydroxyphenyl) propionate]; a sulfur-based antioxidant such as dilauryl-3,3′-thiodipropionate, dimyristyl-3,3′-thiodipropionate, distearyl-3,3′-thiodipropionate, ditridecyl-3,3′-thiodipropionate or pentaerythrityl tetrakis(3-laurylthiopropionate); and a phosphorus-based antioxidant such as tridecyl phosphite, triphenyl phosphite, tris(2,4-di-t-butylphenyl) phosphite, 2-ethylhexyldiphenyl phosphite, diphenyl tridecyl phosphite, 2,2-methylenebis(4,6-di-t-butylphenyl) octyl phosphite, distearyl pentaerythritol diphosphite, bis(2,6-di-t-butyl-4-methylphenyl) pentaerythritol diphosphite, or 2-[[2,4,8,10-tetrakis(1,1-dimethyl ethyl)dibenzo[d,f][1,3,2]dioxaphosphepin-6-yl]oxy]-N,N-bis[2-[[2,4,8,10-tetrakis(1,1-dimethylethyl)dibenzo[d,f][1,3,2]dioxaphosphepin-6-yl]oxy]-ethyl]ethanamine.

Further, a known adhesiveness-imparting agent that is not a component (F) may be contained therein, if necessary, in a non-limiting manner for imparting an adhesiveness or stickiness (pressure-sensitive adhesiveness) so long as it is capable of achieving the functionality and effects of the present invention. Examples of such adhesiveness-imparting agent include a urethane resin, a phenolic resin and a terpene resin

The amount of the other additives to be added therein varies depending on the purpose of the composition; they are added in an amount not larger than 10% by mass with respect to the whole composition.

### [Production Method of Composition]

The underfill composition of the present invention can be produced by the method described below.

For example, the components (A) to (F) (where the component (F) is an optional component, and therefore is not always added) may be simultaneously or separately mixed, and stirred, dissolved and/or dispersed while performing a heating treatment, if necessary, to obtaining a mixture of the components (A) to (F). Preferably, the mixture of the components (A), (B), (D), (E) and (F) may also be added with the epoxy resin curing agent (C), which is then stirred, dissolved and/or dispersed to obtain a mixture of the components (A) to (F). Further, depending on intended use, at least one of a flame retardant, a polymerization initiator and an ion trapping agent may be added to and mixed with the mixture of the components (A) to (F). As for each component, one kind thereof may be used alone, or two or more kinds thereof may be used in combination.

In the production method of the composition, there are no particular restrictions on a device for performing mixing, stirring and dispersing. Specifically, there may be used, for example, a grinding machine equipped with stirring and heating devices, a twin roll mill, a triple roll mill, a ball mill, a planetary mixer, or a mass colloider; these devices may be appropriately combined at the time of use.

### [Cured Product of Underfill Composition]

The conditions and methods for curing and molding the underfill composition of the present invention may be those that are known in the art, which are preferably performed by first curing the composition by heat in an oven at 100 to 120° C. for at least 0.5 hours, and then curing the same by heat in an oven at 150 to 175° C. for at least 3 hours. Heating at 100 to 120° C. for longer than 0.5 hours can prevent a void that develops after being cured. Further, heating at 150 to 175° C. for longer than 3 hours results in a product having sufficient properties of the cured product.

### Working Examples

The present invention is described in greater detail hereunder with reference to working and comparative examples; the present invention shall not be limited to the following working examples. Here, in Tables 1 to 4, the amounts of the components added are expressed as parts by mass.

The components used in the working and comparative examples are as shown below. Here, in the following description, the number average molecular weight (Mn) refers to a number average molecular weight in terms of polystyrene that is measured by gel permeation chromatography (GPC) under the measurement conditions as set forth in the following.

### [GPC Measurement Conditions]

Developing solvent: Tetrahydrofuran (THF)
Flow rate: 0.35 mL/min
Detector: Differential refractive index detector (RI)
Column: TSK Guardcolumn SuperH-L
   TSKgel SuperHZ4000 (4.6 mmI.D.×15 cm×1)
   TSKgel SuperHZ3000 (4.6 mmI.D.×15 cm×1)
   TSKgel SuperHZ2000 (4.6 mmI.D.×15 cm×2)
   (All manufactured by Tosoh Corporation)
Column temperature: 40° C.
Sample injection volume: 5 μL (THF solution with a concentration of 0.2% by mass)

### (A) Citraconimide Compound

### Synthesis Example 1 (Production of Citraconimide Compound, Formula (2))

A reaction solution prepared by adding 52.29 g of 2-methylpentamethylenediamine (0.45 mol), 111.0 g of citraconic anhydride (0.99 mol) and 150 g of toluene to a 2 L four-necked glass flask equipped with a stirrer, a Dean-Stark tube, a cooling condenser and a thermometer, followed by stirring the reaction solution at 80° C. for three hours to synthesize an amic acid. Next, 40 g of methanesulfonic acid was added to the reaction solution, followed by raising the temperature to 110° C., and then stirring the reaction solution for 16 hours while distilling away water generated as a by-product. After the stirring was over, the reaction solution was then washed five times with 200 g of ion-exchange water. Later, by performing stripping under a reduced pressure at 60° C., there was obtained 130.1 g (yield 95%) of a target product being a brown liquid at room temperature (formula (2), (A1), number average molecular weight (Mn) of 510).

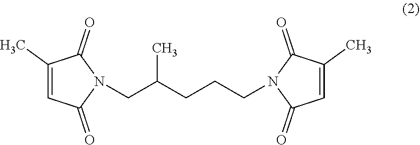

### Synthesis Example 2 (Production of Citraconimide Compound, Formula (3))

A reaction solution was prepared by adding 71.2 g of 2,2,4-trimethylhexamethylenediamine (0.45 mol), 111.0 g of citraconic anhydride (0.99 mol) and 150 g of toluene to a 2 L four-necked glass flask equipped with a stirrer, a Dean-Stark tube, a cooling condenser and a thermometer, followed by stirring the reaction solution at 80° C. for three hours to synthesize an amic acid. Next, 40 g of methanesulfonic acid was added to the reaction solution, followed by raising the temperature to 110° C., and then stirring the reaction solution for 16 hours while distilling away water generated as a by-product. After the stirring was over, the reaction solution was then washed five times with 200 g of ion-exchange water. Later, by performing stripping under a reduced pressure at 60° C., there was obtained 149.7 g (yield 96%) of a target product being a brown liquid at room temperature (formula (3), (A2), number average molecular weight Mn of 590).

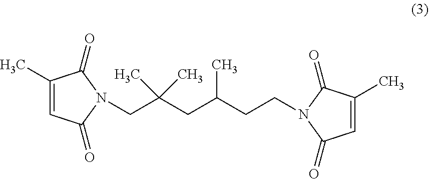

### (B) Epoxy Resin

(B1)Bisphenol A-type epoxy resin (jER828EL by Mitsubishi Chemical Holdings Corporation, liquid at 25° C., epoxy group equivalent 189)
(B2) Biphenyl aralkyl-type epoxy resin (NC-3000 by Nippon Kayaku Co., Ltd., softening point 56° C., epoxy group equivalent 273)

### (C) Epoxy Resin Curing Agent

(C1) Novolac-type allylphenolic resin (MEH-8000H by Meiwa Plastic Industries, Ltd., phenolic hydroxy group equivalent 141)
(C2) 3,3′-diethyl-4,4′-diaminodiphenylmethane (KAYAHARD AA by Nippon Kayaku Co., Ltd., amino group equivalent 63.5)
(C3) 4-methylcyclohexane-1,2-dicarboxylic acid anhydride (RIKACID MH by New Japan Chemical Co., Ltd., acid anhydride equivalent 168)
(C4) Active ester compound having dicyclopentadiene-type phenolic resin structure (HPC-8000-65T by DIC Corporation, active ester group equivalent 223, toluene varnish/solid content 65%); expressed as solid contents in Tables 1 to 4

### (D) Curing Accelerator

(D1) 2-ethyl-4-methylimidazole (2E4MZ by SHIKOKU KASEI HOLDINGS CORPORATION)
(D2) 2-phenyl-4-methylimidazole (2P4MZ by SHIKOKU KASEI HOLDINGS CORPORATION)
(D3)Bis(tetrabutylphosphonium)dihydrogen pyromellitate (BTBP-pyromellitic acid by HOKKO CHEMICAL INDUSTRY CO., LTD.)
(D4) Trimellitic acid salt (36%) and phenol resin salt (46%) of 1,8-diazabicyclo[5.4.0]-7-undecene (DBU) (U-CAT SA838A manufactured by San-Apro Ltd.)

### (E) Inorganic Filler

(E1) Perfectly spherical silica filler manufactured by the sol-gel process (KE-S150 manufactured by Nippon Shokubai Co., Ltd.; Average particle diameter of 1.5 μm)
(E2) Spherical silica filler manufactured by the vaporized metal combustion method (SO-E4-SX manufactured by ADMATECHS CO., LTD; Average particle diameter of 1.0 μm)
(E3) Molten silica (LVS-516H manufactured by TATSUMORI LTD.; Average particle diameter of 0.6 μm)
   (F) Silane coupling agent
(F1) 8-glycidoxyoctyltrimethoxysilane (KBM-4803: manufactured by Shin-Etsu Chemical Co., Ltd)
(F2) 8-methacryloxyoctyltrimethoxysilane (KBM-5803: manufactured by Shin-Etsu Chemical Co., Ltd)
(F3) N-2-(aminoethyl)-8-aminooctyltrimethoxysilane (KBM-6803: manufactured by Shin-Etsu Chemical Co., Ltd)
(F4) 3-glycidoxypropyltrimethoxysilane (KBM-403: manufactured by Shin-Etsu Chemical Co., Ltd)

### (G) Maleimide Compound

1,6-bismaleimide-(2,2,4-trimethyl) hexane (BMI-TMH by Daiwakasei Industry Co., LTD.)

This maleimide compound (G) was used in the comparative example 4 so as to show the superiority of the citraconimide compound.

Underfill compositions were obtained by mixing the above components at the compounding ratios (parts by mass) shown in Tables 1 to 4. The compositions and the cured products of the respective compositions were evaluated for the penetration property, relative permittivity, dielectric tangent, coefficient of linear thermal expansion (CTE) and adhesiveness using the methods as shown below. The results are as shown in Tables 1 to 4. Here, the “equivalent ratio” in Tables 1 to 4 refers to a ratio of a molar equivalent (active hydrogen equivalent) of the functional groups in the epoxy resin curing agent as the component (C) to 1 molar equivalent of the epoxy groups in the epoxy resin as the component (B).

### 1. Infiltration Test

A 50 μm-thick polyimide tape was secured by sandwiching the tape between two 30 mm×50 mm glass plates to prepare a test specimen having a 50 μm gap. The test specimen was heated to 120° C., and the respective underfill compositions of the working and comparative examples were poured into their gaps, and the time required for each composition to infiltrate the specimen by the depth of 30 mm was measured. When the infiltration of 30 mm took 180 seconds or less, the composition was rated as “A”. When the infiltration of 30 mm took longer than 180 seconds, the composition was rated as “B”. When the infiltration of 30 mm was unsuccessful, the composition was rated as “C”.

### 2. Relative Permittivity, Dielectric Tangent

A frame having a diameter of 200 mm and a thickness of 150 μm was prepared, and each underfill composition prepared in the working and comparative examples was then sandwiched between such frame and a PET film (E7006 by TOYOBO CO., LTD.) having a thickness of 50 μm and being subjected to a mold release treatment, followed by using a vacuum press machine (by Nikko-Materials Co., Ltd.) to perform molding at 180° C. for 5 min, thereby obtaining a cured product. The cured product was then taken out of the PET film, and was subjected to the main curing process under a condition(s) of 165° C., three hours to obtain a cured resin film.

A network analyzer (E5063-2D5 by Keysight Technologies) and a stripline (by KEYCOM Corporation) were then connected to such cured resin film to measure the relative permittivity and dielectric tangent of the cured resin film at a frequency of 10 GHz.

### 3. Measurement of Coefficient of Thermal Linear Expansion (CTE)

The above-mentioned cured products were respectively processed in the form of 5×5×15 mm test strips, which were respectively placed in a thermal dilatometer TMA8140C manufactured by Rigaku Corporation. The heating up program was set at 10° C./min, and a setting of applying a constant load of 19.6 mN was set up to then measure the change in dimension of the test strips in a range from 25 to 260° C. The coefficients of linear thermal expansion were calculated from the change in dimension in a range from 0 to 40° C. to determine the CTE.

### 4. Measurement of Adhesiveness

Each underfill composition was applied to a 10 mm×10 mm silicon wafer, followed by mounting a 2 mm×2 mm silicon chip thereon and then curing the resin composition under the above curing conditions, thus obtaining a test specimen for testing adhesiveness. A shear adhesion force of the specimen was measured using a bond tester DAGE-SERIES-4000 PXY (by Nordson Advanced Technology Japan K.K.) after the specimen was left to stand for 40 seconds on a stage at 260° C., and the measured value was used as an initial value. An adhesion area between the frame of the specimen and the resin was 4 mm².

Moreover, each test specimen was placed in a pressure cooker to be exposed to a saturated water vapor of 2.03×10⁵ Pa at 121° C. for 72 hours, and then the specimen was cooled to room temperature after which the specimen was subjected to the measurement of shear adhesion force using the method similar to the one as explained above. Adhesion force retention rates after high-temperature and high-humidity storage were respectively calculated by (shear adhesion force at 260° C. after being exposed to a saturated water vapor of 2.03×10⁵ Pa at 121° C. for 72 hours)/initial value×100(%). The initial values and retention rates of adhesion force after high-temperature and high-humidity storage of the respective test specimens are shown in Tables 3 and 4.

TABLE 1

| | Working | Working | Working | Working | Working | Working |
|---|---|---|---|---|---|---|
| | example 1 | example 2 | example 3 | example 4 | example 5 | example 6 |
| Citraconimide compound (A1) | 70 | 80 | 90 | 95 | | 90 |
| Citraconimide compound (A2) | | | | | 90 | |
| Epoxy resin (B1) | 24 | 16 | 8 | 4 | 8 | |
| Epoxy resin (B2) | | | | | | |
| Epoxy resin curing agent (C1) | 6 | 4 | 2 | 1 | 2 | 2 |
| Epoxy resin curing agent (C2) | | | | | | |
| Epoxy resin curing agent (C3) | | | | | | |
| Epoxy resin curing agent (C4) | | | | | | |
| Curing accelerator (D1) | 1 | 1 | 1 | 1 | 1 | 1 |
| Curing accelerator (D2) | | | | | | |
| Curing accelerator (D3) | | | | | | |
| Curing accelerator (D4) | | | | | | |
| Inorganic filler (E1) | 101 | 101 | 101 | 101 | 101 | 101 |
| Inorganic filler (E2) | | | | | | |
| Inorganic filler (E3) | | | | | | |
| Inorganic filler content (mass %) | 50 | 50 | 50 | 50 | 50 | 50 |
| Maleimide compound | | | | | | |
| Equivalent ratio | 3.0 | 3.0 | 3.0 | 3.0 | 3.0 | 2.1 |
| Infiltration test | A | A | A | A | A | A |
| Relative permittivity (10 GHz) | 3.0 | 2.9 | 29 | 29 | 3.0 | 2.9 |
| Dielectric tangent (10 GHz) | 0.0083 | 0.0065 | 0.0044 | 0.0031 | 0.0044 | 0.0043 |
| CTE (ppm/° C.) | 32 | 33 | 33 | 33 | 33 | 33 |

| | Working | Working | Working | Working | Working |
|---|---|---|---|---|---|
| | example 7 | example 8 | example 9 | example 10 | example 11 |
| Citraconimide compound (A1) | 90 | 90 | 90 | 90 | 95 |
| Citraconimide compound (A2) | | | | | |
| Epoxy resin (B1) | 3 | 8 | 8 | 8 | 4 |
| Epoxy resin (B2) | 5 | | | | |
| Epoxy resin curing agent (C1) | 2 | 2 | 2 | 2 | 1 |
| Epoxy resin curing agent (C2) | | | | | |
| Epoxy resin curing agent (C3) | | | | | |
| Epoxy resin curing agent (C4) | | | | | |
| Curing accelerator (D1) | 1 | | | | 1 |
| Curing accelerator (D2) | | 1 | | | |
| Curing accelerator (D3) | | | 1 | | |
| Curing accelerator (D4) | | | | 1 | |
| Inorganic filler (E1) | 101 | 101 | 101 | 101 | 40 |
| Inorganic filler (E2) | | | | | |
| Inorganic filler (E3) | | | | | |
| Inorganic filler content (mass %) | 50 | 50 | 50 | 50 | 20 |
| Maleimide compound | | | | | |
| Equivalent ratio | 2.4 | 3.0 | 3.0 | 3.0 | 3.0 |
| Infiltration test | A | A | A | A | A |
| Relative permittivity (10 GHz) | 2.9 | 3.0 | 3.0 | 3.0 | 2.7 |
| Dielectric tangent (10 GHz) | 0.0045 | 0.0046 | 0.0047 | 0.0046 | 0.0047 |
| CTE (ppm/° C.) | 33 | 32 | 33 | 33 | 44 |

TABLE 2

| | Working | Working | Working | Working | Working | Working |
|---|---|---|---|---|---|---|
| | example 12 | example 13 | example 14 | example 15 | example 16 | example 17 |
| Citraconimide compound (A1) | 70 | 90 | 90 | 90 | 90 | 90 |
| Citraconimide compound (A2) | | | | | | |
| Epoxy resin (B1) | 24 | 8 | 8 | 8 | 8 | 8 |
| Epoxy resin (B2) | | | | | | |
| Epoxy resin curing agent (C1) | 6 | | | | 2 | 2 |
| Epoxy resin curing agent (C2) | | 2 | | | | |
| Epoxy resin curing agent (C3) | | | 2 | | | |
| Epoxy resin curing agent (C4) | | | | 2 | | |
| Curing accelerator (D1) | 1 | 1 | 1 | 1 | 1 | 1 |
| Curing accelerator (D2) | | | | | | |
| Curing accelerator (D3) | | | | | | |
| Curing accelerator (D4) | | | | | | |
| Inorganic filler (E1) | 162 | 101 | 101 | 101 | | |
| Inorganic filler (E2) | | | | | 101 | |
| Inorganic filler (E3) | | | | | | 101 |
| Inorganic filler content (mass %) | 80 | 50 | 50 | 50 | 50 | 50 |
| Maleimide compound | | | | | | |
| Equivalent ratio | 3.0 | 1.3 | 3.6 | 4.7 | 3.0 | 3.0 |
| Infiltration test | B | A | A | B | B | B |
| Relative permittivity (10 GHz) | 3.3 | 3.0 | 3.0 | 3.0 | 3.0 | 3.0 |
| Dielectric tangent (10 GHz) | 0.0064 | 0.0039 | 0.0037 | 0.0042 | 0.0030 | 0.0028 |
| CTE (ppm/° C.) | 15 | 33 | 33 | 33 | 32 | 33 |

| | Comparative | Comparative | Comparative | Comparative | Comparative |
|---|---|---|---|---|---|
| | example 1 | example 2 | example 3 | example 4 | example 5 |
| Citraconimide compound (A1) | 90 | 90 | 90 | | 90 |
| Citraconimide compound (A2) | | | | | |
| Epoxy resin (B1) | 10 | | 8 | 24 | 8 |
| Epoxy resin (B2) | | | | | |
| Epoxy resin curing agent (C1) | | 10 | 2 | 6 | 2 |
| Epoxy resin curing agent (C2) | | | | | |
| Epoxy resin curing agent (C3) | | | | | |
| Epoxy resin curing agent (C4) | | | | | |
| Curing accelerator (D1) | 1 | 1 | | 1 | 1 |
| Curing accelerator (D2) | | | | | |
| Curing accelerator (D3) | | | | | |
| Curing accelerator (D4) | | | | | |
| Inorganic filler (E1) | 101 | 101 | 101 | 101 | |
| Inorganic filler (E2) | | | | | |
| Inorganic filler (E3) | | | | | |
| Inorganic filler content (mass %) | 50 | 50 | 50 | 50 | 0 |
| Maleimide compound | | | | 70 | |
| Equivalent ratio | — | — | 3.0 | 3.0 | 3.0 |
| Infiltration test | C | C | A | C | A |
| Relative permittivity (10 GHz) | 3.0 | 2.8 | Insufficient | 3.1 | 2.6 |
| | | | curing | | |
| Dielectric tangent (10 GHz) | 0.010 | 0.0028 | Insufficient | 0.0090 | 0.0056 |
| | | | curing | | |
| CTE (ppm/° C.) | 32 | 34 | Insufficient | 32 | 56 |
| | | | curing | | |

TABLE 3

| | Working | Working | Working | Working | Working | Working | Working |
|---|---|---|---|---|---|---|---|
| | example | example | example | example | example | example | example |
| | 18 | 19 | 20 | 21 | 22 | 23 | 24 |
| Biscitraconimide compound (A1) | 70 | 80 | 90 | 95 | | 90 | 90 |
| Biscitraconimide compound (A2) | | | | | 90 | | |
| Epoxy resin (B1) | 24 | 16 | 8 | 4 | 8 | | 3 |
| Epoxy resin (B2) | | | | | | 8 | 8 |
| Epoxy resin curing agent (C1) | 6 | 4 | 2 | 1 | 2 | 2 | 2 |
| Epoxy resin curing agent (C2) | | | | | | | |
| Epoxy resin curing agent (C3) | | | | | | | |
| Epoxy resin curing agent (C4) | | | | | | | |
| Curing accelerator (D1) | 1 | 1 | 1 | 1 | 1 | 1 | 1 |
| Curing accelerator (D2) | | | | | | | |
| Curing accelerator (D3) | | | | | | | |
| Curing accelerator (D4) | | | | | | | |
| Silane coupling agent (F1) | | | | | | | |
| Silane coupling agent (F2) | | | | | | | |
| Silane coupling agent (F3) | | | | | | | |
| Silane coupling agent (F4) | | | | | | | |
| Spherical silica (E1) | 102 | 102 | 102 | 102 | 102 | 102 | 102 |
| Spherical silica (E2) | | | | | | | |
| Spherical silica content (mass %) | 50 | 50 | 50 | 50 | 50 | 50 | 50 |
| Equivalent ratio | 3.0 | 3.0 | 3.0 | 3.0 | 3.0 | 2.1 | 2.4 |
| Infiltration test | A | A | A | A | A | A | A |
| Relative permittivity (10 GHz) | 3.0 | 2.9 | 2.9 | 2.9 | 3.0 | 2.9 | 2.9 |
| Dielectric tangent (10 GHz) | 0.0085 | 0.0066 | 0.0045 | 0.0032 | 0.0045 | 0.0045 | 0.0046 |
| Initial adhesion force (MPa, 260° C.) | 22 | 21 | 20 | 20 | 20 | 19 | 20 |
| Adhesion force retention rate (%) | 58 | 56 | 55 | 51 | 55 | 54 | 53 |

| | Working | Working | Working | Working | Working |
|---|---|---|---|---|---|
| | example | example | example | example | example |
| | 25 | 26 | 27 | 28 | 29 |
| Biscitraconimide compound (A1) | 90 | 90 | 90 | 90 | 90 |
| Biscitraconimide compound (A2) | | | | | |
| Epoxy resin (B1) | 8 | 8 | 8 | 8 | 8 |
| Epoxy resin (B2) | | | | | |
| Epoxy resin curing agent (C1) | 2 | 2 | 2 | 2 | 2 |
| Epoxy resin curing agent (C2) | | | | | |
| Epoxy resin curing agent (C3) | | | | | |
| Epoxy resin curing agent (C4) | | | | | |
| Curing accelerator (D1) | | | | 1 | 1 |
| Curing accelerator (D2) | 1 | | | | |
| Curing accelerator (D3) | | 1 | | | |
| Curing accelerator (D4) | | | 1 | | |
| Silane coupling agent (F1) | | | 1 | | |
| Silane coupling agent (F2) | | | | 1 | |
| Silane coupling agent (F3) | | | | | 1 |
| Silane coupling agent (F4) | | | | | |
| Spherical silica (E1) | 102 | 102 | 102 | 102 | 102 |
| Spherical silica (E2) | | | | | |
| Spherical silica content (mass %) | 50 | 50 | 50 | 50 | 50 |
| Equivalent ratio | 3.0 | 3.0 | 3.0 | 3.0 | 3.0 |
| Infiltration test | A | A | A | A | A |
| Relative permittivity (10 GHz) | 3.0 | 3.0 | 3.0 | 3.0 | 3.0 |
| Dielectric tangent (10 GHz) | 0.0047 | 0.0047 | 0.0047 | 0.0047 | 0.0047 |
| Initial adhesion force (MPa, 260° C.) | 19 | 20 | 19 | 20 | 21 |
| Adhesion force retention rate (%) | 55 | 55 | 55 | 56 | 55 |

TABLE 4

| | Working | Working | Working | Working | Working | Working |
|---|---|---|---|---|---|---|
| | exam- | exam- | exam- | exam- | exam- | exam- |
| | ple 30 | ple 31 | ple 32 | ple 33 | ple 34 | ple 35 |
| Biscitraconimide compound (A1) | 90 | 90 | 70 | 90 | 90 | 90 |
| Biscitraconimide compound (A2) | | | | | | |
| Epoxy resin (B1) | 8 | 8 | 4 | 24 | 8 | 8 |
| Epoxy resin (B2) | | | | | | |
| Epoxy resin curing agent (C1) | 2 | 2 | 1 | 6 | | |
| Epoxy resin curing agent (C2) | | | | | 2 | |
| Epoxy resin curing agent (C3) | | | | | | 2 |
| Epoxy resin curing agent (C4) | | | | | | |
| Curing accelerator (D1) | 1 | 1 | 1 | 1 | 1 | 1 |
| Curing accelerator (D2) | | | | | | |
| Curing accelerator (D3) | | | | | | |
| Curing accelerator (D4) | | | | | | |
| Silane coupling agent (F1) | 3 | 1 | 1 | 1 | 1 | 1 |
| Silane coupling agent (F2) | | | | | | |
| Silane coupling agent (F3) | | | | | | |
| Silane coupling agent (F4) | | 1 | | | | |
| Spherical silica (E1) | 102 | 102 | 26 | 408 | 102 | 102 |
| Spherical silica (E2) | | | | | | |
| Spherical silica content (mass %) | 50 | 50 | 20 | 80 | 50 | 50 |
| Equivalent ratio | 3.0 | 3.0 | 3.0 | 3.0 | 1.3 | 3.6 |
| Infiltration test | A | A | A | B | A | A |
| Relative permittivity (10) GHz) | 3.0 | 3.0 | 2.7 | 3.3 | 3.0 | 3.0 |
| Dielectric tangent (10 GHz) | 0.0050 | 0.0048 | 0.0048 | 0.0066 | 0.0041 | 0.0038 |
| Initial adhesion force (MPa, 260° C.) | 20 | 21 | 18 | 20 | 20 | 21 |
| Adhesion force retention rate (%) | 57 | 55 | 35 | 68 | 55 | 54 |

| | Working | Working | Working | Working | Comparative |
|---|---|---|---|---|---|
| | exam- | exam- | exam- | exam- | exam- |
| | ple 36 | ple 37 | ple 38 | ple 39 | ple 6 |
| Biscitraconimide compound (A1) | 90 | 90 | 90 | 90 | 90 |
| Biscitraconimide compound (A2) | | | | | |
| Epoxy resin (B1) | 8 | 8 | 8 | 8 | 8 |
| Epoxy resin (B2) | | | | | |
| Epoxy resin curing agent (C1) | | 2 | 2 | 2 | 2 |
| Epoxy resin curing agent (C2) | | | | | |
| Epoxy resin curing agent (C3) | | | | | |
| Epoxy resin curing agent (C4) | 2 | | | | |
| Curing accelerator (D1) | 1 | 1 | 1 | 1 | 1 |
| Curing accelerator (D2) | | | | | |
| Curing accelerator (D3) | | | | | |
| Curing accelerator (D4) | | | | | |
| Silane coupling agent (F1) | 1 | 1 | | | 1 |
| Silane coupling agent (F2) | | | | | |
| Silane coupling agent (F3) | | | | | |
| Silane coupling agent (F4) | | | | 1 | |
| Spherical silica (E1) | 102 | | 102 | 102 | |
| Spherical silica (E2) | | 102 | | | |
| Spherical silica content (mass %) | 50 | 50 | 50 | 50 | 0 |
| Equivalent ratio | 4.7 | 3.0 | 3.0 | 3.0 | 3.0 |
| Infiltration test | B | B | A | A | A |
| Relative permittivity (10) GHz) | 3.0 | 3.0 | 2.9 | 2.9 | 2.6 |
| Dielectric tangent (10 GHz) | 0.0043 | 0.0044 | 0.0044 | 0.0045 | 0.0058 |
| Initial adhesion force (MPa, 260° C.) | 20 | 19 | 13 | 15 | <1 |
| Adhesion force retention rate (%) | 56 | 53 | 36 | 40 | <1 |

As can be seen from the results shown in Tables 1 and 2, it became clear that an underfill composition containing the citraconimide compound, epoxy resin, epoxy resin curing agent, curing accelerator and organic filler was superior in infiltration property into a thin film, and the cured product thereof exhibits excellent dielectric properties (a low relative permittivity and a low dielectric tangent).

Further, as can be seen from the results shown in Tables 3 and 4, it became clear that an underfill composition containing the biscitraconimide compound, epoxy resin, epoxy resin curing agent, curing accelerator, silane coupling agent having specific structures and spherical silica was superior in infiltration property into a thin film, that the cured product thereof exhibits excellent dielectric properties (a low relative permittivity and a low dielectric tangent), and that the composition exhibits enhanced adhesiveness to a base material.

The composition of the present invention is therefore suitable for use as an underfill material.

What is claimed is:

1. An underfill composition comprising the components of:
(A) a citraconimide compound;
(B) an epoxy resin;
(C) an epoxy resin curing agent;
(D) a curing accelerator; and
(E) an inorganic filler.

2. The underfill composition according to claim 1, wherein, based on the mass of the whole composition, the citraconimide compound (A) is contained therein in an amount of 10 to 75% by mass, the epoxy resin (B) is contained therein in an amount of 0.1 to 75% by mass, the epoxy resin curing agent (C) is contained therein in an amount such that a molar equivalent ratio of functional groups in the component (C) that are reactive with epoxy groups to 1 molar equivalent of epoxy groups in the epoxy resin (B) is 0.1 to 8.0, and the curing accelerator (D) is contained therein in an amount of 0.0001 to 15% by mass.

3. The underfill composition according to claim 1, wherein the citraconimide compound (A) is a biscitraconimide compound represented by the following formula (1): 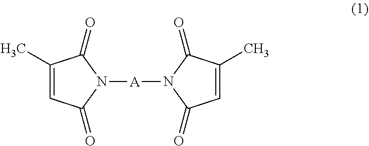
wherein A in the formula (1) represents a divalent organic group.

4. The underfill composition according to claim 3, wherein A in the formula (1) is selected from dimer acid frame-derived hydrocarbon groups, and the groups expressed by the following structures: 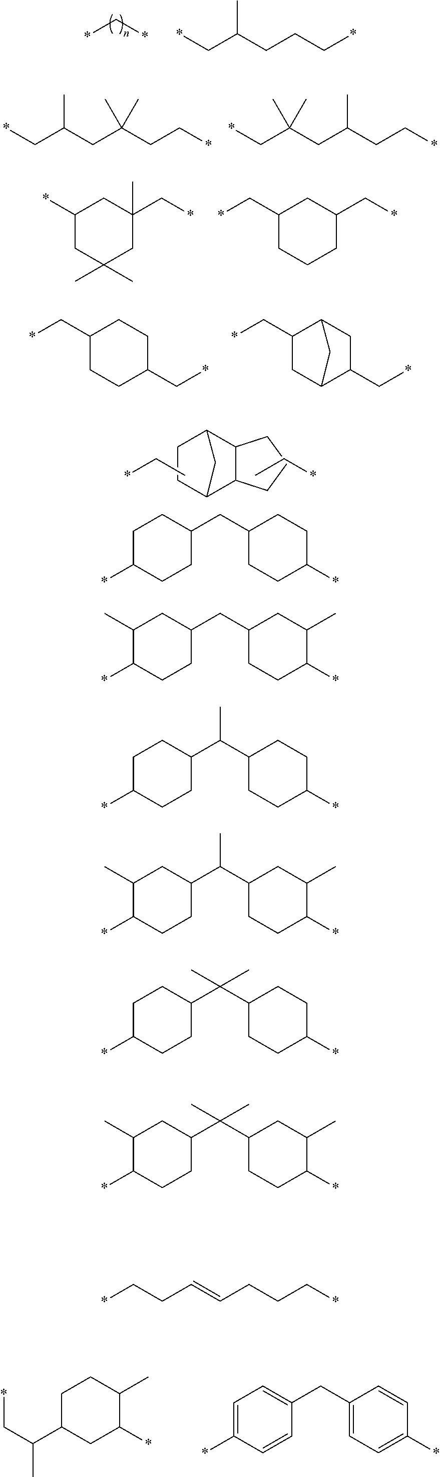 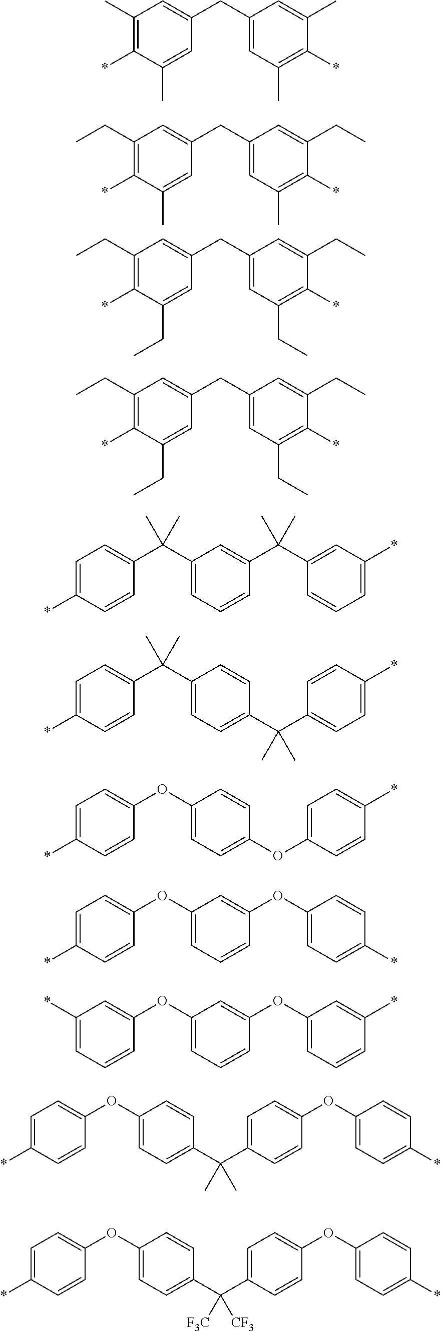 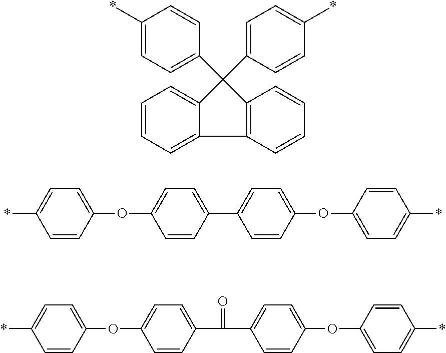
wherein each * represents a bond to a nitrogen atom in the citraconimide group; and n is 1 to 20.

5. The underfill composition according to claim 3, wherein A in the formula (1) is a group selected from the aliphatic hydrocarbon groups expressed by the following structures: 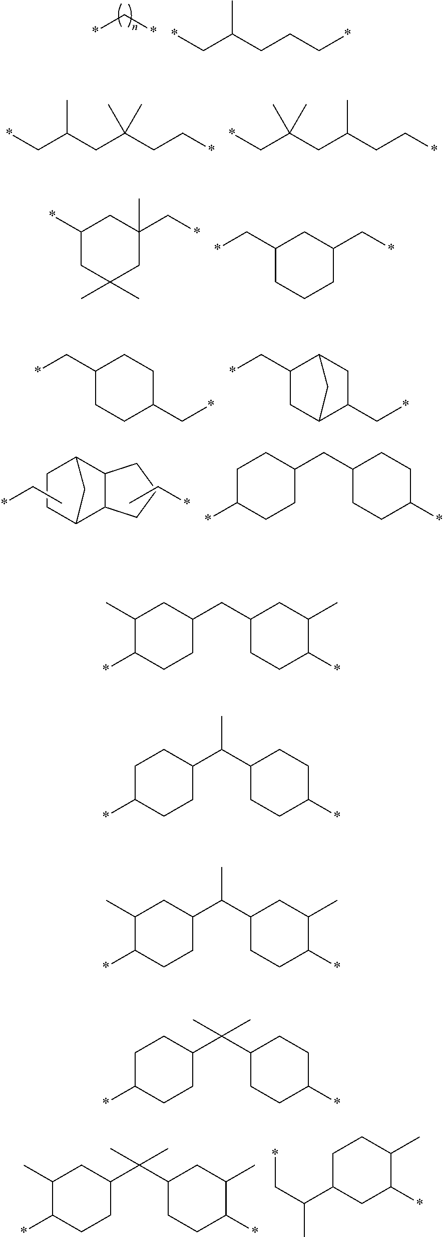
wherein each * represents a bond to a nitrogen atom in the citraconimide group; and n is 1 to 20.

6. The underfill composition according to claim 1, wherein the citraconimide compound (A) has a number average molecular weight of 200 to 10,000.

7. The underfill composition according to claim 1, wherein the epoxy resin (B) has at least two epoxy groups per each molecule.

8. The underfill composition according to claim 1, wherein the epoxy resin curing agent (C) is at least one selected from an amine compound, a phenolic compound, an acid anhydride compound and an active ester compound.

9. The underfill composition according to claim 1, wherein the curing accelerator (D) contains at least one selected from an imidazole-based curing accelerator, an organic phosphorus-based curing accelerator and a tertiary amine-based curing accelerator.

10. The underfill composition according to claim 1, wherein the inorganic filler (E) is a spherical silica having an average particle diameter of 0.01 to 5 μm, wherein the spherical silica is manufactured by a sol-gel process.

11. The underfill composition according to claim 1, wherein the inorganic filler (E) is contained therein in an amount of 20 to 80% by mass per 100% by mass of the whole components in the composition.

12. The underfill composition according to claim 1, further comprising at least one silane coupling agent represented by the following formula (4): 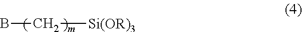
wherein, in the formula (4), each R independently represents a methyl group or an ethyl group, m is a number of 8 to 12, and B is a monovalent organic group having, at its terminal end, one functional group selected from an epoxy group, a glycidoxy group, an acryloxy group, a methacryloxy group and an amino group.
